(19) United States
(12) Patent Application Publication
(10) Pub. No.: US 2007/0068623 A1
(43) Pub. Date: Mar. 29, 2007

(54) Apparatus for the removal of a set of byproducts from a substrate edge and methods therefor

(76) Inventors: Yunsang Kim, Fremont, CA (US); Andrew D. Bailey III, Fremont, CA (US); Hyungsuk Alexander Yoon, Fremont, CA (US)

Correspondence Address: IPSG, P.C., P.O. BOX 700640, SAN JOSE, CA, 95170-0640, US

(21) Appl. No.: 11/237,327

(22) Filed: Sep. 27, 2005

(51) Int. Cl. C23F 1/00; H01L 21/306

(52) U.S. Cl. 156/345.3; 156/345.43; 156/345.33; 216/67

(57) ABSTRACT

A plasma processing system including a plasma chamber for processing a substrate is disclosed. The apparatus includes a chuck configured for supporting a first surface of the substrate. The apparatus also includes a plasma resistant barrier disposed in a spaced-apart relationship with respect to a second surface of the substrate, the second surface being opposite the first surface, the plasma resistant barrier substantially shielding a center portion of the substrate and leaving an annular periphery area of the second surface of the substrate substantially unshielded by the plasma resistant barrier. The apparatus further includes at least one powered electrode, the powered electrode operating cooperatively with the plasma resistant barrier to generate confined plasma from a plasma gas, the confined plasma being substantially confined to the annular periphery portion of the substrate and away from the center portion of the substrate.

### BACKGROUND OF THE INVENTION

The present invention relates in general to substrate manufacturing technologies and in particular to apparatus for the removal of a set of byproducts from a substrate edge and methods therefor.

In the processing of a substrate, e.g., a semiconductor substrate or a glass panel such as one used in flat panel display manufacturing, plasma is often employed. As part of the processing of a substrate for example, the substrate is divided into a plurality of dies, or rectangular areas, each of which will become an integrated circuit. The substrate is then processed in a series of steps in which materials are selectively removed (etching) and deposited. Control of the transistor gate critical dimension (CD) on the order of a few nanometers is a top priority, as each nanometer deviation from the target gate length may translate directly into the operational speed and or operability of these devices.

In a first exemplary plasma process, a substrate is coated with a thin film of hardened emulsion (such as a photoresist mask) prior to etching. Areas of the hardened emulsion are then selectively removed, causing parts of the underlying layer to become exposed. The substrate is then placed in a plasma processing chamber on a substrate support structure comprising a mono-polar or bi-polar electrode, called a chuck. An appropriate set of plasma gases is then flowed into the chamber and struck to form a plasma to etch exposed areas of the substrate.

During an etch process, it is not uncommon for polymer byproducts (composed of Carbon (C), Oxygen (O), Nitrogen (N), Fluorine (F), etc.) to form on the top and bottom of a substrate edge. That is, a surface area on the annular periphery of the substrate where no dies are present. However, as successive polymer layers are deposited as the result of several different etch processes, organic bonds that are normally strong and adhesive will eventually weaken and peel or flake off, often onto another substrate during transport. For example, substrates are commonly moved in sets between plasma processing systems via substantially clean containers, often called cassettes. As a higher positioned substrate is repositioned in the container, byproduct particles may fall on a lower substrate where dies are present, potentially affecting device yield.

In view of the foregoing, there are desired apparatus for the removal of a set of byproducts from a substrate edge and methods therefor.

### SUMMARY OF THE INVENTION

The invention relates, in one embodiment, to a plasma processing system including a plasma chamber for processing a substrate. The apparatus includes a chuck configured for supporting a first surface of the substrate. The apparatus also includes a plasma resistant barrier disposed in a spaced-apart relationship with respect to a second surface of the substrate, the second surface being opposite the first surface, the plasma resistant barrier substantially shielding a center portion of the substrate and leaving an annular periphery area of the second surface of the substrate substantially unshielded by the plasma resistant barrier. The apparatus further includes at least one powered electrode, the powered electrode operating cooperatively with the plasma resistant barrier to generate confined plasma from a plasmagas, the confined plasma being substantially confined to the annular periphery portion of the substrate and away from the center portion of the substrate.

The invention relates, in one embodiment, to a method for removing a set of byproducts from a substrate. The method includes configuring a chuck for supporting a first surface of the substrate. The method also includes positioning a plasma resistant barrier in a spaced-apart relationship with respect to a second surface of the substrate, the second surface being opposite the first surface, the plasma resistant barrier substantially shielding a center portion of the substrate and leaving an annular periphery area of the second surface of the substrate substantially unshielded by the plasma resistant barrier. The method further includes configuring at least one powered electrode to operate cooperatively with the plasma resistant barrier to generate a plasma from a plasma gas, the confined plasma being substantially confined to the annular periphery portion of the substrate and away from the center portion of the substrate. The method also includes configuring an inert gas delivery arrangement to introduce an inert gas into a gap defined by the center portion of the substrate and the plasma resistant barrier, wherein when the confined plasma is generated, the set of byproducts is substantially removed.

The invention relates, in one embodiment, to a method for removing a set of byproducts from a substrate in a plasma chamber. The method includes configuring at least one powered electrode, to strike a plasma from a plasma gas, wherein the powered electrode is electrically coupled to the chuck when a plasma is struck. The method also includes positioning a plasma resistant barrier in a spaced-apart relationship with the substrate, wherein the plasma resistant barrier is configured to substantially confine the plasma to an annular periphery portion of the substrate and away from the center portion of the substrate, and wherein the plasma resistant barrier and the substrate define a gap. The method further includes configuring an inert gas delivery arrangement to introduce an inert gas into the gap, wherein when the plasma is struck, the set of byproducts is removed from the annular periphery portion of the substrate.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1A illustrates a simplified diagram of an inductively coupled plasma processing system with a perimeter induction coil for edge byproduct removal, according to an embodiment of the invention;

FIG. 1B illustrates a simplified diagram of an inductively coupled plasma processing system with a top induction coil for edge byproduct removal, according to an embodiment of the invention;

FIG. 2 illustrates a simplified diagram of a capacitively coupled plasma processing system for edge byproduct removal, according to an embodiment of the invention;

FIG. 3 illustrates a simplified diagram showing the gas configuration for the plasma processing systems, as shown in FIG. 1A-2, according to an embodiment of the invention;

FIG. 4 illustrates a simplified diagram of a plasma processing system for edge byproduct removal, in which an inert barrier is supported with a bottom attachment support structure, according to an embodiment of the invention;

FIG. 5 illustrates a simplified diagram of a plasma processing system for edge byproduct removal, in which an inert barrier is supported with a lateral attachment support structure, according to an embodiment of the invention; and

FIG. 6 illustrates a simplified method for the removal of a set of byproducts from a substrate edge, according to an embodiment of the invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

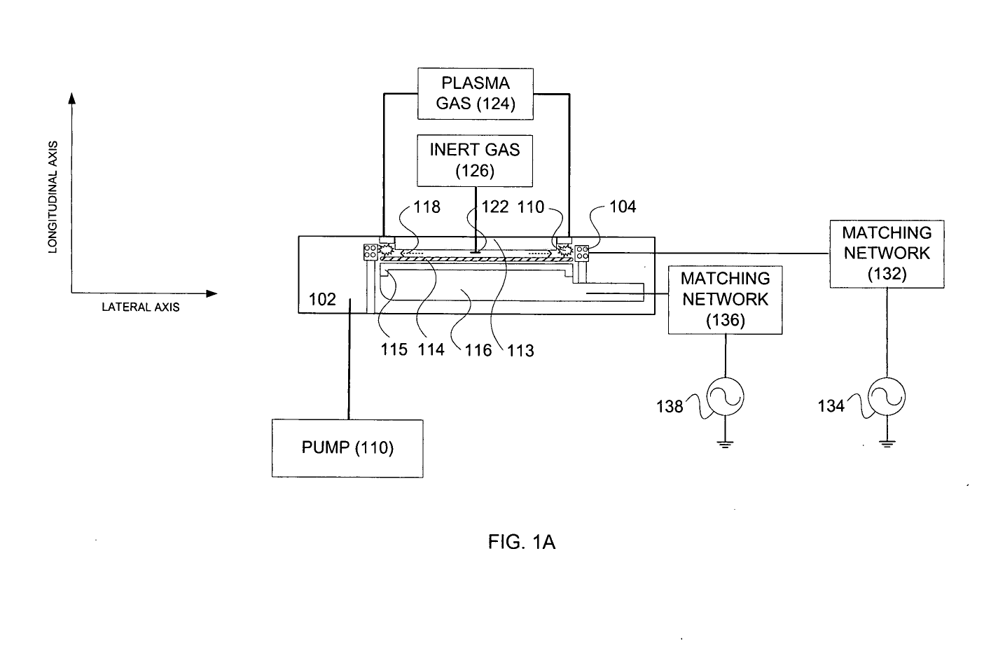

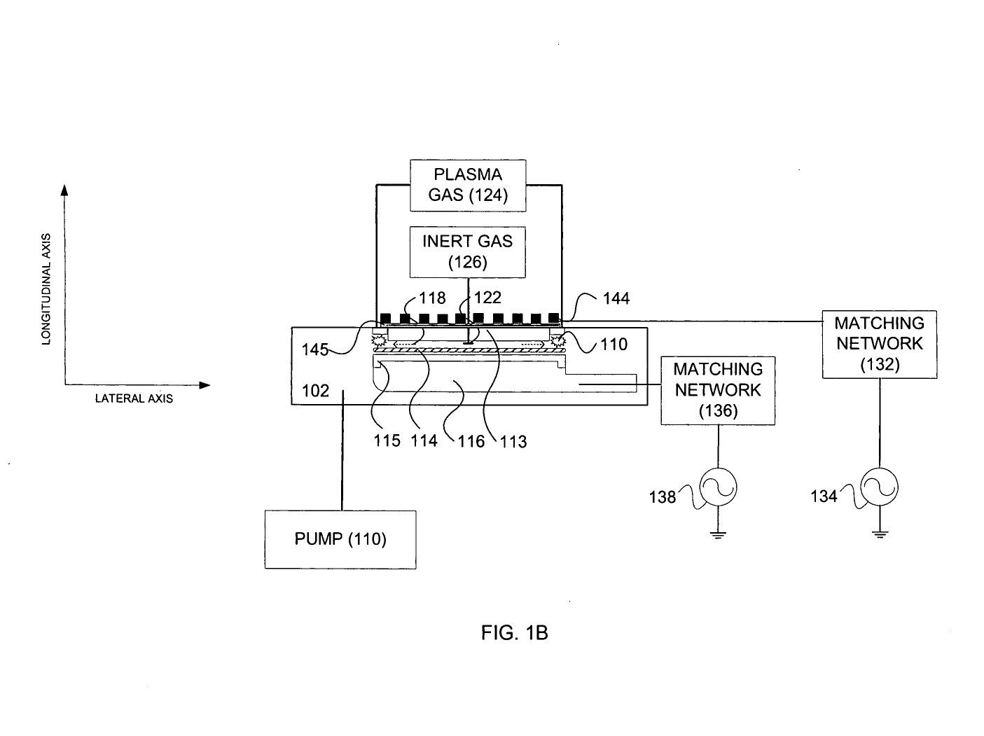

Referring now to FIG. 1A, a simplified diagram is shown of an inductively coupled plasma processing system with a perimeter induction coil (powered electrode) for edge byproduct removal, according to an embodiment of the invention. In an advantageous manner, an inert barrier placed above the substrate, in combination with an inert gas flowing from the substrate center toward the substrate annular periphery, and positioned above the substrate, may substantially isolate the plasma to the substrate annular periphery, allowing byproducts to be rapidly removed while minimizing potential damage to exposed electrical structures on the substrate surface (center area).

In general, a substrate with a set of edge byproducts is positioned in a plasma chamber with edge ring 115 on an electrostatic chuck (chuck) 116. That is, the chuck may be configured to support a first (bottom) surface of the substrate. Perimeter induction coil 104 is generally configured to strike plasma 110 by inducing a time-varying electric current in a set of plasma gases 124 (e.g., O₂, CF₄, C₂F₆, Ar, etc.) optimized for byproduct removal. In an embodiment, perimeter induction coil 104 is configured as a ring or doughnut with an inner diameter (along a lateral axis) at least as large as the diameter of substrate 114.

Further coupled to perimeter induction coil 104, is typically a matching network 132 that may be further coupled to RF generator 134. Matching network 132 attempts to match the impedance of RF generator 134, which typically operates from about 2 MHz to about 27 MHz, and about 50 ohms, to that of the plasma 110. Additionally, a second RF energy source 138 may also be coupled through matching network 136 to the substrate 114 in order to create a bias with the plasma, and direct the plasma away from structures within the plasma processing system and toward the substrate.

In addition, in order to substantially isolate or confine plasma 110 to a surface area at the edge (annular periphery) of the substrate, plasma resistant barrier 113 (e.g., quartz, sapphire, etc.) may be placed at a gap distance just above but not touching a second (top) surface of substrate 114. That is, substrate 114 is positioned between plasma resistant barrier 113 and chuck 116. In an embodiment, plasma resistant barrier 113 is configured with a diameter (along a lateral axis) that is smaller than a substrate diameter (along a lateral axis). In an embodiment, plasma resistant barrier 113 is attached to a top surface of plasma chamber 102. In addition, a second inert gas 126 (center inert) flow may also be channeled between plasma resistant barrier 113 and substrate 114 with an inert gas delivery arrangement, creating a positive pressure force from the substrate center to the annular periphery of the substrate 114, and substantially isolating plasma 110 away from electrical structures on exposed portions of the substrate surface. For example, the inert gas delivery arrangement may include a set of nozzles, tubing, valves, a mass flow controller, pumps, etc. As byproducts are removed from substrate 114, they are vented from plasma chamber 102 by pump 110.

In an embodiment, the plasma is a low pressure plasma. For example, in an inductively coupled plasma processing system with a power setting of about 100 W to about 500 W, at a pressure of about 5 mTorr to about 1 Torr, and with a plasma gas (O₂, CF₄, C₂F₆, AR, etc.) and a inert gas (e.g., He, Ar, N₂, etc.), a gap distance of less than about 0.5 mm may be sufficient to isolate plasma 110 at the substrate annular periphery and thus minimize any potential damage to electrical structures on exposed portions of the substrate surface. In an embodiment, a gap distance is preferably between about 0.1 mm and about 0.5 mm. In an embodiment, a gap distance is more preferably between about 0.2 mm and about 0.4 mm. In an embodiment, a gap distance is most preferably about 0.3 mm.

In an embodiment, the plasma is an atmospheric or high pressure plasma. For example, in an inductively coupled atmospheric plasma processing system with a power setting of about 100 W to about 500 W, at an ambient pressure, and with a plasma gas (O₂, CF₄, C₂F₆, He, etc.) and a inert gas (e.g., He, Ar, N₂, etc.), a gap distance of less than about 0.1 mm may be sufficient to isolate plasma 110 at the substrate annular periphery and thus minimize any potential damage to electrical structures on exposed portions of the substrate surface

In an embodiment, a gap distance is preferably between about 0.04 mm and about 0.1 mm. In an embodiment, a gap distance is more preferably between about 0.05 mm and about 0.09 mm. In an embodiment, a gap distance is most preferably about 0.07 mm. Advantages of the invention include the removal of a set of byproducts from a substrate edge without substantially damaging electrical structures on exposed portions of the substrate surface.

Referring now to FIG. 1B, a simplified diagram is shown of an inductively coupled plasma processing system with a top induction coil (powered electrode) for edge byproduct removal according to an embodiment of the invention. In general, a substrate with a set of edge byproducts is positioned in a plasma chamber with edge ring 115 on an electrostatic chuck (chuck) 116. That is, the chuck may be configured to support a first (bottom) surface of the substrate. Top induction coil 144, physically separated from plasma 110 by an inert plasma resistant barrier 145 (e.g. ceramic, quartz, etc.), is generally configured to strike plasma 110 by inducing a time-varying electric current in a set of plasma gases 124 (e.g., O₂, CF₄, C₂F₆, Ar, etc.) optimized for byproduct removal. In an embodiment, top induction coil 104 is configured as a set of rings. In an embodiment, at least one ring has an inner diameter (along a lateral axis) at least as large as the diameter of substrate 114.

Further coupled to top induction coil 144, is typically a matching network 132 that may be further coupled to RF generator 134. Matching network 132 attempts to match the impedance of RF generator 134, which typically operates from about 2 MHz to about 27 MHz, and about 50 ohms, to that of the plasma 110. Additionally, a second RF energy source 138 may also be coupled through matching network 136 to the substrate 114 in order to create a bias with the plasma, and direct the plasma away from structures within the plasma processing system and toward the substrate.

In addition, in order to substantially isolate or confine plasma 110 to a surface area at the edge (annular periphery) of the substrate, plasma resistant barrier 113 (e.g., quartz, sapphire, etc.) may be placed at a gap distance just above but not touching a second (top) surface of substrate 114. In an embodiment, plasma resistant barrier 113 is configured with a diameter (along a lateral axis) that is smaller than a substrate diameter (along a lateral axis). That is, substrate 114 is positioned between plasma resistant barrier 113 and chuck 116. In an embodiment, plasma resistant barrier 113 is attached to a top surface of plasma chamber 102. In addition, a second inert gas 126 (inert gas) flow may also be channeled between plasma resistant barrier 113 and substrate 114 with an inert gas delivery arrangement, creating a positive pressure force from the substrate center to the annular periphery of the substrate 114, and substantially isolating plasma 110 away from electrical structures on exposed portions of the substrate surface. As byproducts are removed from substrate 114, they are vented from plasma chamber 102 by pump 110.

In an embodiment, the plasma is a low pressure plasma. For example, in an inductively coupled plasma processing system with a power setting of about 100 W to about 500 W, at a pressure of about 5 mTorr to about 1 Torr, and with a plasma gas (O₂, CF₄, C₂F₆, AR, etc.) and a inert gas (e.g., He, Ar, N₂, etc.), a gap distance of less than about 0.5 mm may be sufficient to isolate plasma 110 at the substrate annular periphery and thus minimize any potential damage to electrical structures on exposed portions of the substrate surface. In an embodiment, a gap distance is preferably between about 0.1 mm and about 0.5 mm. In an embodiment, a gap distance is more preferably between about 0.2 mm and about 0.4 mm. In an embodiment, a gap distance is most preferably about 0.3 mm.

In an embodiment, the plasma is an atmospheric or high pressure plasma. For example, in an inductively coupled atmospheric plasma processing system with a power setting of about 100 W to about 500 W, at an ambient pressure, and with a plasma gas (O₂, CF₄, C₂F₆, He, etc.) and a inert gas (e.g., He, Ar, N₂, etc.), a gap distance of less than about 0.1 mm may be sufficient to isolate plasma 110 at the substrate annular periphery and thus minimize any potential damage to electrical structures on exposed portions of the substrate surface.

In an embodiment, a gap distance is preferably between about 0.04 mm and about 0.1 mm. In an embodiment, a gap distance is more preferably between about 0.05 mm and about 0.09 mm. In an embodiment, a gap distance is most preferably about 0.07 mm. Advantages of the invention include the removal of a set of byproducts from a substrate edge without substantially damaging electrical structures on exposed portions of the substrate surface.

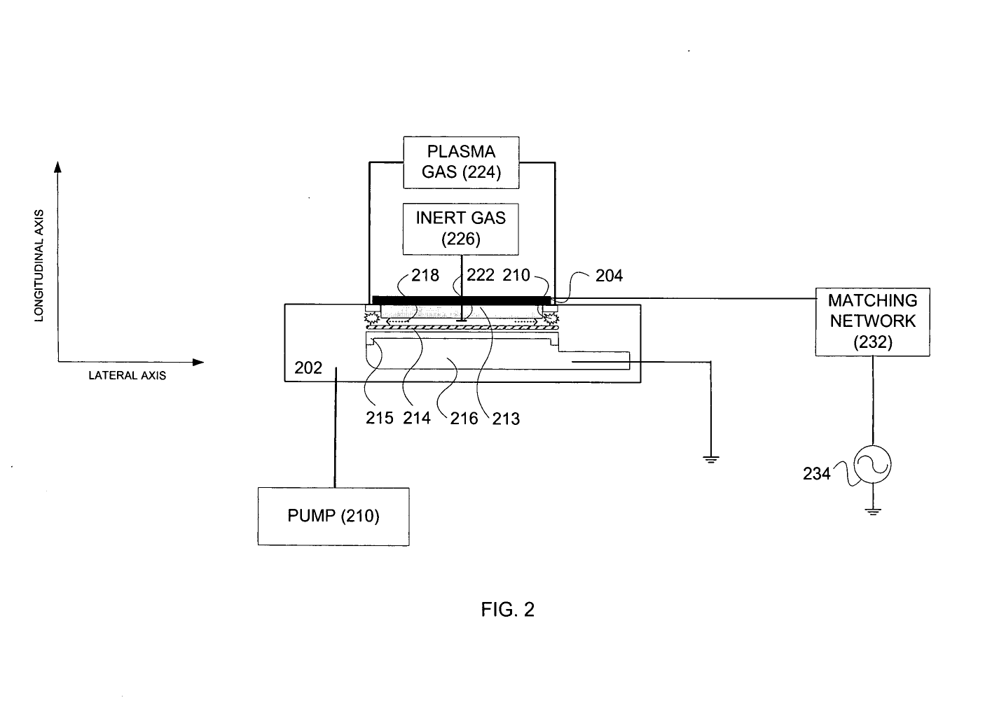

Referring now to FIG. 2, a simplified diagram of a capacitively coupled plasma processing system with a powered electrode for edge byproduct removal is shown, according to an embodiment of the invention. In general, a substrate with a set of edge byproducts is positioned in a plasma chamber with edge ring 215 on a grounded electrostatic chuck (chuck) 216. That is, the chuck may be configured to support a first (bottom) surface of the substrate. Powered electrode 204 is generally configured to strike plasma 210 by inducing a time-varying electric current in a set of plasma gases 224 (e.g., O₂, CF₄, C₂F₆, Ar, etc.) optimized for byproduct removal.

Further coupled to powered electrode 204, is typically a matching network 232 that may be further coupled to RF generator 234. Matching network 232 attempts to match the impedance of RF generator 234, which typically operates from about 2 MHz to about 27 MHz, and about 50 ohms, to that of the plasma 210. In addition, in order to substantially isolate or confine plasma 210 to a surface area at the edge (annular periphery) of the substrate, inert barrier 213 (e.g., quartz, sapphire, etc.) may be placed at a gap distance just above but not touching a second (top) surface of substrate 214.

In an embodiment, inert barrier 213 is configured with a diameter (along a lateral axis) that is smaller than a substrate diameter (along a lateral axis). That is, substrate 214 is positioned between inert barrier 213 and chuck 216. In an embodiment, inert barrier 213 is attached to a top surface of plasma chamber 202. In addition, a second inert gas 226 (inert gas) flow may also be channeled between inert barrier 213 and substrate 214 with an inert gas delivery arrangement, creating a positive pressure force from the substrate center to the substrate annular periphery of the substrate 114, and substantially isolating plasma 210 away from electrical structures on exposed portions of the substrate surface. For example, the inert gas delivery arrangement may include a set of nozzles, tubing, valves, a mass flow controller, pumps, etc. As byproducts are removed from substrate 214, they are vented from plasma chamber 202 by pump 210.

In an embodiment, the plasma is a low pressure plasma. For example, in an inductively coupled plasma processing system with a power setting of about 100 W to about 500 W, at a pressure of about 5 mTorr to about 1 Torr, and with a plasma gas (O₂, CF₄, C₂F₆, AR, etc.) and a inert gas (e.g., He, Ar, N₂, etc.), a gap distance of less than about 0.5 mm may be sufficient to isolate plasma 310 at the substrate annular periphery and thus minimize any potential damage to electrical structures on exposed portions of the substrate surface. In an embodiment, a gap distance is preferably between about 0.1 mm and about 0.5 mm. In an embodiment, a gap distance is more preferably between about 0.2 mm and about 0.4 mm. In an embodiment, a gap distance is most preferably about 0.3 mm.

In an embodiment, the plasma is an atmospheric or high pressure plasma. For example, in an inductively coupled atmospheric plasma processing system with a power setting of about 100 W to about 500 W, at an ambient pressure, and with a plasma gas (O₂, CF₄, C₂F₆, He, etc.) and a inert gas (e.g., He, Ar, N₂, etc.), a gap distance of less than about 0.1 mm may be sufficient to isolate plasma 110 at the substrate annular periphery and thus minimize any potential damage to electrical structures on exposed portions of the substrate surface

In an embodiment, a gap distance is preferably between about 0.04 mm and about 0.1 mm. In an embodiment, a gap distance is more preferably between about 0.05 mm and about 0.09 mm. In an embodiment, a gap distance is most preferably about 0.07 mm. Advantages of the invention include the removal of a set of byproducts from a substrate edge without substantially damaging electrical structures on exposed portions of the substrate surface.

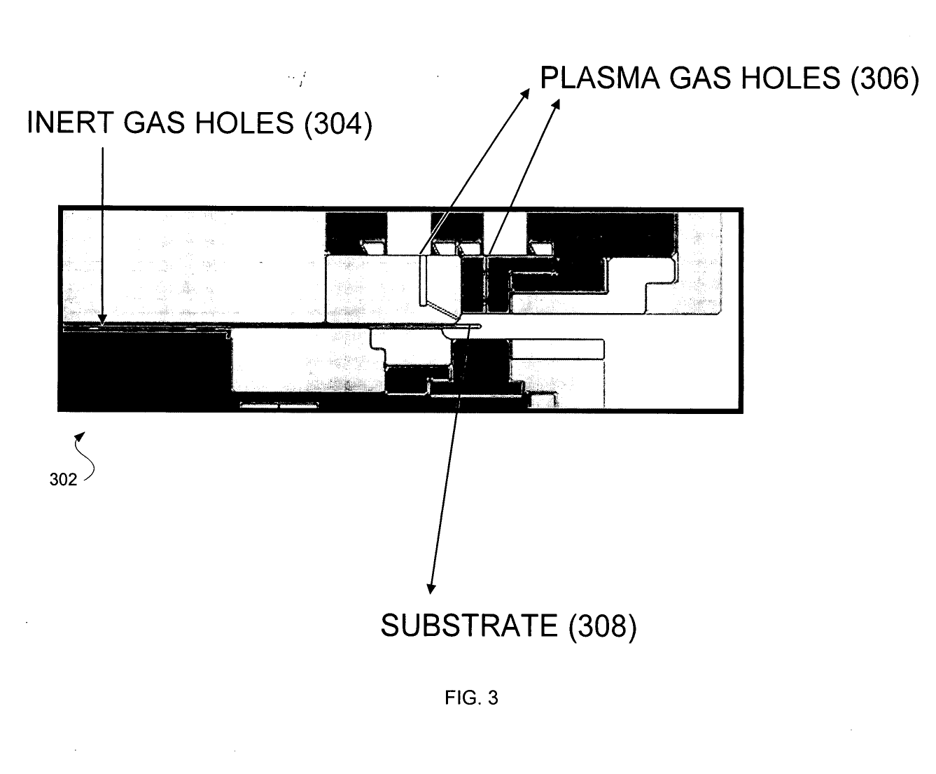

Referring now to FIG. 3, a simplified diagram is shown of the gas configuration for the plasma processing systems, as shown in FIG. 1A-2, according to an embodiment of the invention. As previously described, a set of plasma gases (e.g., O₂, CF₄, C₂F₆, Ar, etc.) may be flowed into plasma chamber 302 through a set of plasma gas holes 306, in order to strike a plasma (not shown) in order to remove a set of edge byproducts from substrate 308. In addition, in order to substantially isolate the plasma (not shown) to a surface area at the edge (annular periphery) of substrate 308, a second inert gas (inert gas) flow may also be channeled through a set of inert gas holes 304, creating a positive pressure force from the substrate center to the substrate annular periphery of the substrate 308, and substantially isolating the plasma not shown) away from electrical structures on exposed portions of the substrate surface. In an embodiment, the set of plasma gas holes 306 is positioned near the edge (annular periphery) of substrate 308. In an embodiment, the set of plasma gas holes 306 is positioned off the edge (annular periphery) of substrate 308. In an embodiment, the set of plasma gas holes 306 is positioned above an inert barrier (not shown). In an embodiment, the set of plasma gas holes 306 is positioned in a powered electrode (not shown).

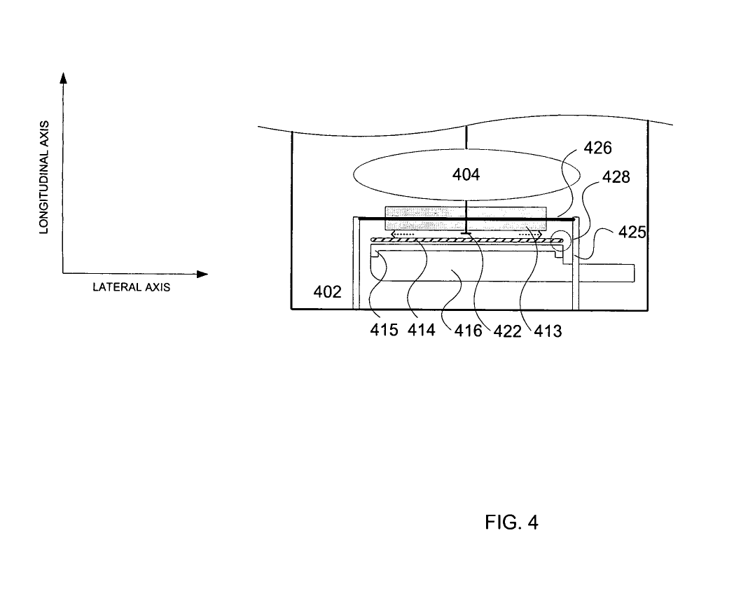

Referring now to FIG. 4, a simplified diagram of a plasma processing system (capacitively coupled, inductively coupled, atmospheric, etc.) for edge byproduct removal, in which an inert barrier is supported with a bottom attachment support structure, according to an embodiment of the invention. In advantageous manner, a bottom attachment support structure may allow edge byproduct removal functionality to be more easily retrofitted into existing plasma processing systems since existing plasma chamber electrodes (e.g., induction coil, powered electrode, grounded electrode, etc.) may not need to be repositioned in order to secure inert barrier 403. The bottom attachment support structure may generally comprise a set of longitudinal support members 425 and a set of lateral support members 426 that may correctly position inert barrier 413 at an appropriate gap distance above substrate 414, such that only substrate edge 420 may be substantially exposed to plasma 424.

In general, plasma 404 is created by flowing a set of plasma gases [not shown] (e.g., O₂, CF₄, C₂F₆, Ar, etc.) into plasma chamber 402, at which point plasma 404 is struck in order to remove a set of edge byproducts from substrate 414, positioned with edge ring 415 on a chuck 416. In an embodiment, lateral support members and longitudinal support members comprise an inert material (e.g., quartz, sapphire, etc.). In an embodiment, the set of longitudinal support members 425 and the set of lateral support members 426 comprise a single manufactured unit. In an embodiment, lateral support members 426 are configured to allow substrate edge 428 to be exposed to a substantial portion of plasma 404. In an embodiment, the set of longitudinal support members 425 is attached to chuck 416.

In addition, a second inert gas flow (not shown) may also be channeled between inert barrier 413 and substrate 414 with an inert gas delivery arrangement (not shown), creating a positive pressure force from the substrate center to the substrate annular periphery of the substrate 414, and substantially isolating plasma 404 away from electrical structures on exposed portions of the substrate surface.

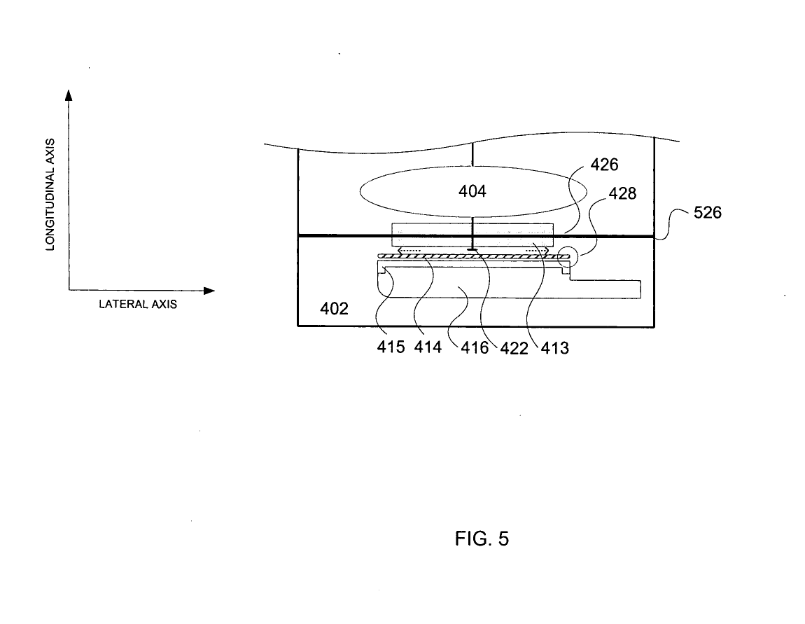

Referring now to FIG. 5, a simplified diagram of a plasma processing system (capacitively coupled, inductively coupled, atmospheric, etc.) for edge byproduct removal, in which an inert barrier is supported with a lateral attachment support structure, according to an embodiment of the invention. In advantageous manner, a lateral attachment support structure may allow edge byproduct removal functionality to be more easily retrofitted into existing plasma processing systems since existing plasma chamber electrodes (e.g., induction coil, powered electrode, grounded electrode, etc.) may not need to be repositioned in order to secure inert barrier 413. The lateral attachment support structure may generally comprise a set of lateral support members 526 that may correctly position inert barrier 413 at an appropriate gap distance above substrate 414, such that only substrate edge 420 may be exposed to plasma 424.

In general, plasma 404 is created by flowing a set of plasma gases (not shown) (e.g., O₂, CF₄, C₂F₆, Ar, etc.) into plasma chamber 402, at which point plasma 404 is struck in order to remove a set of edge byproducts from substrate 414, positioned with edge ring 415 on a chuck 416. In an embodiment, lateral support members comprise an inert material (e.g., quartz, sapphire, etc.). In an embodiment, lateral support members 426 are configured to allow substrate edge 428 to be exposed to a substantial portion of plasma 404. In an embodiment, the set of lateral support members 425 is attached to the plasma chamber walls. In addition, a second inert gas flow [not shown] may also be channeled between inert barrier 413 and substrate 414, creating a positive pressure force from the substrate center to the substrate annular periphery of the substrate 414, and substantially isolating plasma 404 away from electrical structures on exposed portions of the substrate surface.

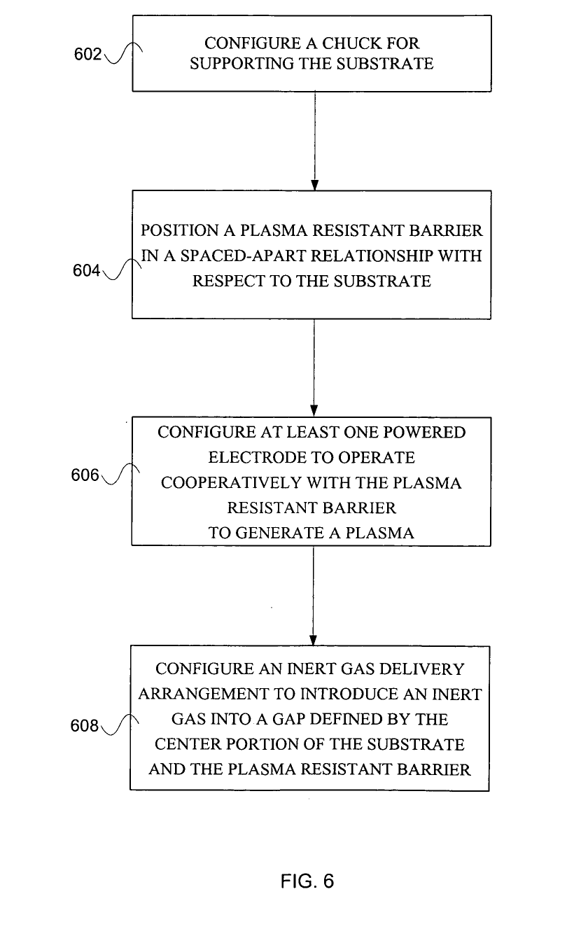

Referring not to FIG. 6, a simplified method for the removal of a set of byproducts from a substrate edge is shown, according to an embodiment of the invention. Initially, at 602, a chuck is configured for supporting the substrate. Next, at 604, a plasma resistant barrier is positioned in a spaced-apart relationship with respect to the substrate. Next, at 606, at least one powered electrode is configured to operate cooperatively with the plasma resistant barrier to generate a plasma from a set of plasma gases. In a embodiment, the set of plasma gases includes at least one of O₂, CF₄, C₂F₆, and Ar. Finally, at 608, an inert gas delivery arrangement is configured to introduce an inert gas into a gap defined by the center portion of the substrate and the plasma resistant barrier. For example, the inert gas delivery arrangement may include a set of nozzles, tubing, valves, a mass flow controller, pumps, etc. In an embodiment, the inert gas includes at least one of He, Ar, and N₂.

While this invention has been described in terms of several preferred embodiments, there are alterations, permutations, and equivalents which fall within the scope of this invention. For example, although the present invention has been described in connection with Lam Research plasma processing systems (e.g., Exelan™, Exelan™ HP, Exelan™ HPT, 2300™, Versys™ Star, etc.), other plasma processing systems may be used. This invention may also be used with substrates of various diameters (e.g., 200 mm, 300 mm, LCD, etc.). Furthermore, the term set as used herein includes one or more of the named element of the set. For example, a set of “X” refers to one or more “X.”

Advantages of the invention include the rapid and safe removal of edge byproducts from a substrate surface. Additional advantages include the ability to easily retrofit the invention into existing plasma processing systems.

Having disclosed exemplary embodiments and the best mode, modifications and variations may be made to the disclosed embodiments while remaining within the subject and spirit of the invention as defined by the following claims.

What is claimed is:

1. A plasma processing system including a plasma chamber for processing a substrate, comprising:
a chuck configured for supporting a first surface of said substrate;
a plasma resistant barrier disposed in a spaced-apart relationship with respect to a second surface of said substrate, said second surface being opposite said first surface, said plasma resistant barrier substantially shielding a center portion of said substrate and leaving an annular periphery area of said second surface of said substrate substantially unshielded by said plasma resistant barrier; and
at least one powered electrode, said powered electrode operating cooperatively with said plasma resistant barrier to generate plasma from a plasma gas, said plasma being substantially confined to said annular periphery portion of said substrate and away from said center portion of said substrate.

2. The plasma processing system of claim 1 wherein said powered electrode has a ring shape that is disposed outside of said annular periphery area of said substrate, an inner diameter of said powered electrode being at least as large as a diameter of said substrate.

3. The plasma processing system of claim 1 wherein said powered electrode represents a top inductive coil that is disposed above said substrate.

4. The plasma processing system of claim 1 wherein said powered electrode represents a capacitive plate that is disposed above said substrate.

5. The plasma processing system of claim 1 further comprising an inert gas delivery arrangement configured to introduce an inert gas into a gap defined by said center portion of said substrate and said plasma resistant barrier.

6. The apparatus of claim 1, wherein said plasma resistant barrier is one of ceramic and quartz.

7. The apparatus of claim 1, wherein said plasma resistant barrier is attached to said plasma chamber with a bottom attachment support structure.

8. The apparatus of claim 1, wherein said plasma resistant barrier is attached to said plasma chamber with a lateral attachment support structure.

7. The apparatus of claim 1, wherein said plasma comprises at least one of O₂, CF₄, C₂F₆, and Ar.

8. The apparatus of claim 1, wherein said inert gas comprises at least one of He, Ar, and N₂.

9. The apparatus of claim 1, wherein said plasma is a low pressure plasma.

10. The apparatus of claim 9, wherein said gap distance is between about 0.1 mm and about 0.5 mm.

11. The apparatus of claim 9, wherein said gap distance is between about 0.2 mm and about 0.4 mm.

12. The apparatus of claim 9, wherein said gap distance is about 0.3 mm.

13. The apparatus of claim 1, wherein said plasma is an atmospheric plasma.

14. The apparatus of claim 13, wherein said gap distance is between about 0.04 mm and about 0.1 mm.

15. The apparatus of claim 13, wherein said gap distance is between about 0.05 mm and about 0.09 mm.

16. The apparatus of claim 13, wherein said gap distance is about 0.07 mm.

17. In a plasma processing system, including a plasma chamber, a method for removing a set of byproducts from a substrate, comprising:
configuring a chuck for supporting a first surface of said substrate;
positioning a plasma resistant barrier in a spaced-apart relationship with respect to a second surface of said substrate, said second surface being opposite said first surface, said plasma resistant barrier substantially shielding a center portion of said substrate and leaving an annular periphery area of said second surface of said substrate substantially unshielded by said plasma resistant barrier; and
configuring at least one powered electrode to operate cooperatively with said plasma resistant barrier to generate a plasma from a plasma gas, said plasma being substantially confined to said annular periphery portion of said substrate and away from said center portion of said substrate;
configuring an inert gas delivery arrangement to introduce an inert gas into a gap defined by said center portion of said substrate and said plasma resistant barrier;
wherein when said plasma is generated, said set of byproducts is substantially removed.

18. The method of claim 17 wherein said powered electrode has a ring shape that is disposed outside of said annular periphery area of said substrate, an inner diameter of said powered electrode being at least as large as a diameter of said substrate.

19. The method of claim 17 wherein said powered electrode includes one of a perimeter inductive coil, a top inductive coil, and a capacitive plate.

20. The method of claim 17, wherein said plasma resistant barrier is one of ceramic and quartz.

21. The method of claim 17, wherein said plasma resistant barrier is attached to said plasma chamber with one of a bottom attachment support structure and a lateral attachment support structure.

22. The method of claim 17, wherein said plasma comprises at least one of O₂, CF₄, C₂F₆, and Ar.

23. The method of claim 17, wherein said inert gas comprises at least one of He, Ar, and N₂.

24. The method of claim 17, wherein said plasma is a low pressure plasma.

25. The method of claim 24, wherein said gap distance is one of between about 0.1 mm and about 0.5 mm.

26. The method of claim 17, wherein said plasma is an atmospheric plasma.

27. The method of claim 26, wherein said gap distance is one of between about 0.04 mm and about 0.1 mm.

28. A method for removing a set of byproducts from a substrate in a plasma chamber, said substrate, comprising:
supporting a substrate on a chuck;
configuring at least one powered electrode, to strike a plasma from a plasma gas, wherein said powered electrode is electrically coupled to said chuck when a plasma is struck;
positioning a plasma resistant barrier in a spaced-apart relationship with said substrate, wherein said plasma resistant barrier is configured to substantially confine said plasma to an annular periphery portion of said substrate and away from said center portion of said substrate, and wherein a bottom surface of said plasma resistant barrier and a top surface of said substrate define a gap;
configuring a inert gas delivery arrangement to introduce an inert gas into said gap;
wherein when said plasma is struck, said set of byproducts is removed from said annular periphery portion of said substrate.
